(19) United States
(12) Patent Application Publication
(10) Pub. No.: US 2006/0226514 A1
(43) Pub. Date: Oct. 12, 2006

(54) Semiconductor epitaxial wafer

(76) Inventors: Hiroshi Jiken, Nagasaki (JP); Hiroshi Jiken, Kanasaki (JP); Yuuichi Nasu, Kanagawa (JP); Takeshi Masuda, Kanagawa (JP)

Correspondence Address: WELSH & KATZ, LTD, 120 S RIVERSIDE PLAZA, 22ND FLOOR, CHICAGO, IL, 60606, US

(21) Appl. No.: 10/550,325

(22) PCT Filed: Mar. 25, 2004
(86) PCT No.: PCT/JP04/04167

§ 371 Date: Sep. 23, 2005

(30) Foreign Application Priority Data
Mar. 26, 2003 (JP) 2003-085089

(51) Int. Cl. H01L 23/58

(52) U.S. Cl. 257/629

(57) ABSTRACT

Multiple epitaxial layers are grown on the front side of a p silicon substrate and no layers are grown on the other side. Among the multiple epitaxial layers the one in contact with the silicon substrate is a first p⁺ epitaxial layer. Since the epitaxial layer is in contact with the p⁺ layer, gettering can be efficiently done also in a low-temperature device manufacturing process, thereby improving the manufacturing yield of an epitaxial wafer. Therefore the manufacturing cost of an epitaxial wafer is reduced.

### TECHNICAL FIELD

The present invention relates to a semiconductor epitaxial wafer in which plural epitaxial layers are stacked only on a front side of a semiconductor substrate, and in which an impurity concentration of the epitaxial layer which is in contact with the semiconductor substrate is made high and an impurity concentration of the semiconductor substrate is made low.

### BACKGROUND ART

Semiconductor epitaxial wafers are used for CPUs and memories such as DRAM. Semiconductor epitaxial wafers are broadly classified as epitaxial wafers in which epitaxial layers are stacked on a front side of a semiconductor substrate and non-epitaxial wafers which have no epitaxial layers.

FIG. 4 is a cross-sectional view of an epitaxial wafer. An epitaxial wafer 40 is the most popular P/P⁺ (PonP⁺) epitaxial wafer and a silicon substrate 41 with a high P⁺ impurity concentration of boron or another impurity (a resistivity of 20/1000(Ω·cm) or less) is used. Further, “P^{X}/P^{Y}” means that a P^{Y} film or substrate is stacked on a P^{X} film or substrate. An epitaxial layer 42 that is boron-doped (a resistivity of approximately 1 (Ω·cm) or more) at a lower concentration than the silicon substrate 41 is stacked on the front side 41a of the silicon substrate 41 and an oxide film 43 is stacked on the back side 41b. Such a structure possesses the following benefits.

A variety of metals are employed as secondary materials in the fabrication process of the wafer constituting a semiconductor device or the substrate thereof and the epitaxial layer 42 is sometimes contaminated by an impurity such as a metal. The contaminant metal impurity sometimes changes or degrades the characteristics of each device formed on the epitaxial layer 42, which reduces the reliability of the devices. Hence, the P⁺ silicon substrate 41 is employed as a gettering site on the epitaxial wafer 40. When a contaminant metal such as Fe or Cu or the like is introduced to the epitaxial wafer 40 from outside the wafer, this contaminant metal impurity has the characteristic of being preferentially introduced to the silicon substrate 41 with a high boron concentration. The content of the contaminant metal impurity of the epitaxial layer 42 is reduced as a result. The epitaxial layer 42 can be rendered defect-less and favorable characteristics can be maintained.

When there is no stacking on the back side 41b of the silicon substrate 41 under high-temperature conditions when an epitaxial layer is grown on the front side 41a of the P⁺ silicon substrate 41, a high concentration of boron becomes gas-like and is discharged. Thereupon, so-called auto-doping, which introduces gas-like boron to the epitaxial layer 42, occurs. When auto-doping occurs, the resistance distribution of the epitaxial layer 42 deteriorates. Therefore, an oxide film 43 is stacked prior to epitaxial growth on the back side of the silicon substrate 41. Boron discharge from the silicon substrate 41 is suppressed by the oxide film 43. Therefore, auto-doping can be prevented.

An epitaxial wafer with a different form from that of the epitaxial wafer 40 shown in FIG. 4 is disclosed in Japanese Patent Application Laid Open No. 10-303207 (herein after referred to as “the document 1”).

FIG. 5 is a cross-sectional view of the epitaxial wafer of the document 1. A silicon substrate 51 with a low P⁻ impurity concentration (resistivity of 1 (Ω·cm) or more) is used for the epitaxial wafer 50. Further, a first P⁺ epitaxial layer 52 is stacked on the back side 51b of the silicon substrate 51 and a second epitaxial layer 53 is stacked on the front side 51a of the silicon substrate 51. A silicon film 54 is stacked on the first epitaxial layer 52.

According to this constitution, the contaminant impurity of the second epitaxial layer 53 is gettered by means of the first epitaxial layer 52.

Where the fabrication process of the epitaxial wafer 50 is concerned, the second epitaxial layer 53 is grown on the front side 51a of the silicon substrate 51 after the first epitaxial layer 52 is grown on the back side 51b of the silicon substrate 51. Although gas-like boron is not discharged from the P⁻ silicon substrate 51 when each epitaxial layer is grown, gas-like boron is discharged from the P⁺ first epitaxial layer 52, that is, the back side of the wafer itself when the second epitaxial layer 53 is grown. Hence, the silicon film 54 is provided and auto-doping is suppressed.

In the case of a conventional epitaxial wafer, an oxide film or epitaxial layer or the like (hereinafter ‘oxide film’ or similar) is stacked on the back side of the silicon substrate. However, when an oxide film or similar is stacked on the back side of the silicon substrate, there are problems such as:

(1) it is possible that the silicon substrate will undergo metal contamination when the oxide film is stacked, which reduces the fabrication yield of the epitaxial wafer;

(2) the degree of flatness of the wafer itself drops because the degree of flatness of the oxide film or similar is low, which reduces the fabrication yield of the epitaxial wafer.

The epitaxial wafer 50 shown in FIG. 5 is also subject to the following problems.

The temperature of the device fabrication process has dropped as the technology has progressed. The contaminant metal does not obtain sufficient thermal energy to permit diffusion to the gettering site in a device fabrication process at a reduced temperature. As a result, it is preferable for the epitaxial layer and gettering site to be as close as possible in order to perform gettering efficiently. However, in the epitaxial wafer 50, the silicon substrate 51 is interposed between the gettered first epitaxial layer 52 and second epitaxial layer 53. That is, gettering is not performed efficiently because the second epitaxial layer 53 and gettering site are separate.

The present invention was conceived in view of the actual state of affairs and the object which the present invention is to resolve is that of reducing the fabrication costs of an epitaxial wafer by efficiently performing gettering even in a low-temperature device fabrication process by establishing a P⁺ layer adjacent to the epitaxial layer, whereby the fabrication yield of the epitaxial wafer is increased.

### DISCLOSURE OF THE INVENTION

Therefore, the first invention is a semiconductor epitaxial wafer having an epitaxial layer stacked on a semiconductor substrate, in which plural epitaxial layers are stacked only on a front side of the semiconductor substrate; an impurity concentration of an epitaxial layer being in contact with the semiconductor substrate among the plural epitaxial layers is high enough for the formation of a gettering site; and an impurity concentration of the semiconductor substrate is low enough for the suppression of impurity discharge from a back side of the semiconductor substrate.

Further, the second invention is a semiconductor epitaxial wafer having an epitaxial layer stacked on a semiconductor substrate, in which plural epitaxial layers are stacked only on a front side of the semiconductor substrate; an impurity concentration of an epitaxial layer being in contact with the semiconductor substrate among the plural epitaxial layers is 2.77×10¹⁷ to 5.49×10¹⁹ (atoms/cm³); and an impurity concentration of the semiconductor substrate is 1.33×10¹⁴ to 1.46×10¹⁶ (atoms/cm³).

Furthermore, the third invention is a semiconductor epitaxial wafer having an epitaxial layer stacked on a semiconductor substrate, in which plural epitaxial layers are stacked only on a front side of the semiconductor substrate; a resistivity of an epitaxial layer being in contact with the semiconductor substrate among the plural epitaxial layers is 0.002 to 0.1 (Ω·cm); and a resistivity of the semiconductor substrate is 1 to 100 (Ω·cm).

The first to third inventions will now be described by using FIG. 1.

An epitaxial wafer 1 is constituted by a silicon substrate 2 and a first epitaxial layer 3 and a second epitaxial layer 4 that are stacked on a front side 2a of the silicon substrate 2. The front side 2a of the silicon substrate 2 is in contact with the first epitaxial layer 3 and there is no stacking on the back side 2b of the silicon substrate 2.

The silicon substrate is constituted by P⁻ silicon, the impurity concentration of which is 1.33×10¹⁴ to 1.46×10¹⁶ (atoms/cm³) and the resistivity is 1 to 100 (Ω·cm).

The first epitaxial layer 3 is constituted by a P⁺ silicon epitaxial layer, the impurity concentration of which is 2.77×10¹⁷ to 5.49×10¹⁹ (atoms/cm³) and the resistivity is 0.002 to 0.1 (Ω·cm).

According to the present invention, because there is a short distance between the gettering site, that is, the first epitaxial layer 3, and the second epitaxial layer 4, gettering can be performed efficiently. Further, because the impurity concentration of the silicon substrate 2 is a low concentration, gas-like impurities are not produced during epitaxial growth. As a result, there is no need to form an oxide film or the like on the back side 2b of the silicon substrate 2 and a variety of problems that accompany oxide film formation (double-sided polishing, metal contamination, a decrease in flatness) are not produced. Hence, the fabrication costs of the epitaxial wafer can be reduced by increasing the fabrication yield of the epitaxial wafer.

Further, the fourth invention is the semiconductor epitaxial wafer according to any one of the first to third inventions, in which the epitaxial layer being in contact with the semiconductor substrate contains boron.

### BRIEF DESCRIPTION OF THE DRAWINGS

FIG. 1 is a cross-sectional view of the epitaxial wafer according to the present invention;

FIG. 2 is a flowchart showing the procedure for stacking the epitaxial layers;

FIG. 3 shows the impurity concentration profile of the epitaxial wafer;

FIG. 4 is a cross-sectional view of a conventional epitaxial wafer; and

FIG. 5 is a cross-sectional view of a conventional epitaxial wafer.

### BEST MODE FOR CARRYING OUT THE INVENTION

An embodiment of the semiconductor epitaxial wafer of the present invention will now be described with reference to the drawings hereinbelow.

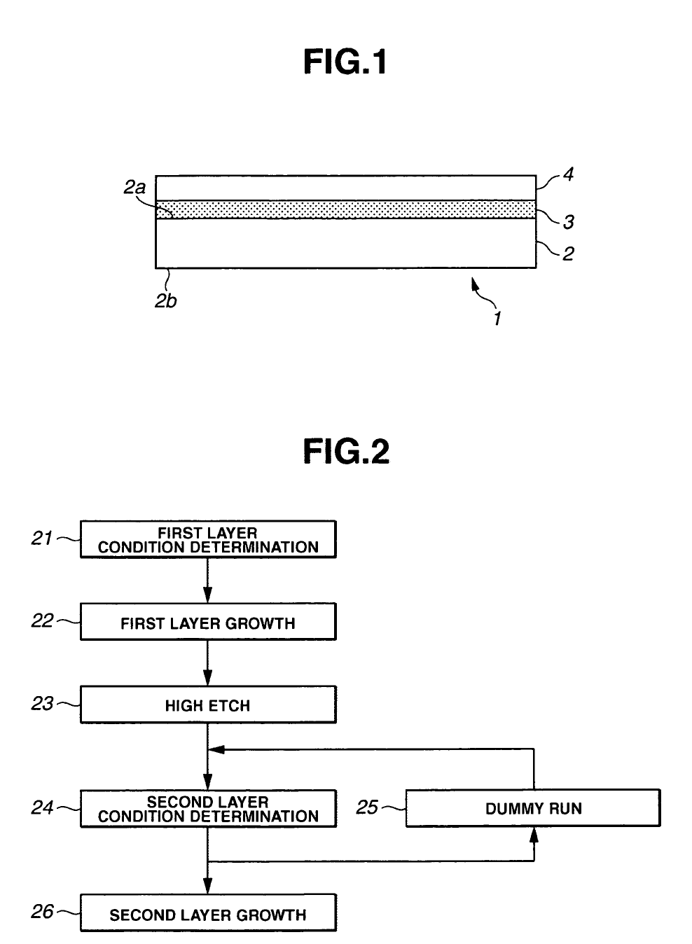

FIG. 1 is a cross-sectional view of the epitaxial wafer according to the present invention.

The epitaxial wafer 1 is constituted by a silicon substrate 2 and a first epitaxial layer 3 and a second epitaxial layer 4 that are stacked on a front side 2a of the silicon substrate 2. The front side 2a of the silicon substrate 2 is in contact with the first epitaxial layer 3 and no layer is stacked on a back side 2b of the silicon substrate 2.

The silicon substrate 2 is constituted by P⁻ silicon crystals with a low impurity concentration. Here, the impurity contained in the silicon substrate 2 is boron and the concentration thereof is 1.33×10¹⁴ to 1.46×10¹⁶ (atoms/cm³). Alternatively, the resistivity of the silicon substrate 2 is 1 to 100 (Ω·cm).

The first epitaxial layer 3 is constituted by a P⁺ silicon epitaxial layer. Here, the impurity contained in the first epitaxial layer 3 is boron and the concentration thereof is 2.77×10¹⁷ to 3.62×10¹⁹ (atoms/cm³). Alternatively, the resistivity of the first epitaxial layer 3 is 0.002 to 0.1 (Ω·cm). The first epitaxial layer 3 functions as a gettering site.

The second epitaxial layer 4 is constituted by a P⁻ silicon epitaxial layer. The respective devices are formed in the second epitaxial layer 4 in a device fabrication process.

Another epitaxial layer with a lower concentration or higher resistivity than the concentration or the resistivity of the first epitaxial layer 3 may be stacked between the first epitaxial layer 3 and the second epitaxial layer 4. The silicon substrate 2 may be doped with nitrogen. The Ni gettering performance improves when the silicon substrate 2 is doped with nitrogen. The nitrogen doping amount is preferably 3×10¹³ (atoms/cm³) or more.

A method of stacking the epitaxial layers 3 and 4 on the silicon substrate 2 will be described next.

FIG. 2 is a flowchart showing the procedure for stacking the epitaxial layers.

An example of conditions for growing the respective epitaxial layers is shown in Table 1.

TABLE 1

| | First epitaxial layer | | Second epitaxial layer | |
|---|---|---|---|---|
| Film thickness | 3 | (μm) | 6 | (μm) |
| Resistivity | 3/1000 | (Ω · cm) | 10 | (Ω · cm) |
| Dopant type | B2H6 | | B2H6 | |
| Dopant concentration | 15% | | 0.01% | |
| H2Bake temperature | 1200 | (° C.) | 1200 | (° C.) |
| Growth temperature | 1100 | (° C.) | 1100 | (° C.) |
| Growth/Rate | 3.62 | (μm/min) | 3.66 | (μm/min) |
| Dilution H2 flow amount | 2 | (slm) | 16 | (slm) |
| Dopant gas flow amount | 450 | (sccm) | 100 | (sccm) |
| Mixing gas flow amount | 200 | (sccm) | 174 | (sccm) |

A monitor wafer is introduced to the furnace before introducing the silicon substrate to the furnace to allow the epitaxial layers to undergo the vapor phase growth, and conditions for the film thickness and resistivity of the first epitaxial layer are determined (step 21) under the conditions shown in Table 1 (for the supply and temperature of a variety of gases). Assuming a state where an epitaxial layer with the film thickness and resistivity shown in Table 1 is obtained, a P⁻ silicon substrate extracted from silicon crystals is introduced to the furnace to permit growth of the first epitaxial layer on the front side of the silicon substrate (step 22). Here, vapor phase growth of a normal epitaxial layer is performed. Once growth of the first epitaxial layer has ended, a process to clean the inside of the furnace known as “High Etch” is performed after the wafer has been evacuated to a load lock chamber (step 23).

“High Etch” is performed on the following reasons. A high concentration dopant gas is supplied to the furnace when the first epitaxial layer is grown. In order to grow the second epitaxial layer after the first epitaxial layer has been grown, a low-concentration dopant gas is supplied to the furnace. However, when the high-concentration dopant or a byproduct thereof remains in the furnace, the second epitaxial layer is affected by the dopant discharged from the residual high-concentration dopant byproduct. As a result, the desired impurity concentration and resistivity cannot be obtained. Therefore, “High Etch” is performed in order to remove the high-concentration dopant or byproduct that remains in the furnace. As for a specific method, HCL is introduced to the furnace for approximately three minutes under the condition 15 (slm). When dopant gas is not removed from the inside of the furnace in one “High Etch”, “High Etch” is repeated plural times.

When “High Etch” is completed, the monitor wafer is re-introduced to the furnace and conditions for the film thickness and resistivity of the second epitaxial layer are determined under the conditions shown in Table 1 (step 24). Thereupon, as a result of the effects of the residual high-concentration dopant, the resistivity of the epitaxial layer sometimes does not rise. In this case, the monitor wafer is re-introduced to the furnace and conditions for the film thickness and resistivity of the second epitaxial layer are determined after a dummy operation has been performed (step 25). Once a state where an epitaxial layer with the film thickness and resistivity shown in Table 1 has been obtained, the evacuated silicon wafer is introduced to the furnace, and the second epitaxial layer is allowed to grow on the first epitaxial layer that has been grown first (step 26). Here, vapor phase growth of a normal epitaxial layer is performed.

As shown in Table 1, although B₂H₆ (diborane) is used as the dopant gas that contains boron in this embodiment, BCl₃ (boron trichloride) may be used.

The resistivity (or impurity concentration), film thickness, and gettering capacity of the epitaxial layer used as the gettering site will be described next.

As shown in levels 1 to 11 of Table 2, the epitaxial wafer of the present invention is manufactured and the front side and the back side of the wafer are purposely contaminated with Fe by immersing each wafer in an Fe ion solution. The Fe contamination amount is 2×10¹³ (atoms/cm²) and is confirmed by the ICS-MS method. Further, the epitaxial wafer shown in levels 12 to 14 is also fabricated accordingly and the same processing was executed. The epitaxial wafer of levels 12 to 14 is the epitaxial wafer that has been used prior to the present invention.

TABLE 2

| | | First epitaxial layer | | Second epitaxial layer | |
|---|---|---|---|---|---|
| | Silicon substrate | Resistivity | Film thickness | Resistivity | Film thickness |
| Level | (shows resistivity in [ ]) | (Ω · cm) | (μm) | (Ω · cm) | (μm) |
| 1 | P⁻[10(Ω · cm)] | 100/1000 | 1 | 10 | 5 |
| 2 | P⁻[10(Ω · cm)] | 100/1000 | 5 | 10 | 5 |
| 3 | P⁻[10(Ω · cm)] | 100/1000 | 30 | 10 | 5 |
| 4 | P⁻[10(Ω · cm)] | 50/1000 | 1 | 10 | 5 |
| 5 | P⁻[10(Ω · cm)] | 50/1000 | 5 | 10 | 5 |
| 6 | P⁻[10(Ω · cm)] | 50/1000 | 30 | 10 | 5 |
| 7 | P⁻[10(Ω · cm)] | 15/1000 | 1 | 10 | 5 |
| 8 | P⁻[10(Ω · cm)] | 15/1000 | 2 | 10 | 5 |
| 9 | P⁻[10(Ω · cm)] | 15/1000 | 5 | 10 | 5 |
| 10 | P⁻[10(Ω · cm)] | 15/1000 | 10 | 10 | 5 |
| 11 | P⁻[10(Ω · cm)] | 15/1000 | 30 | 10 | 5 |
| 12 | P⁺[15/1000(Ω · cm)] | — | — | 10 | 5 |
| 13 | P⁻[10(Ω · cm)] | — | — | 10 | 5 |
| 14 | P⁻[10(Ω · cm)] | — | — | — | — |

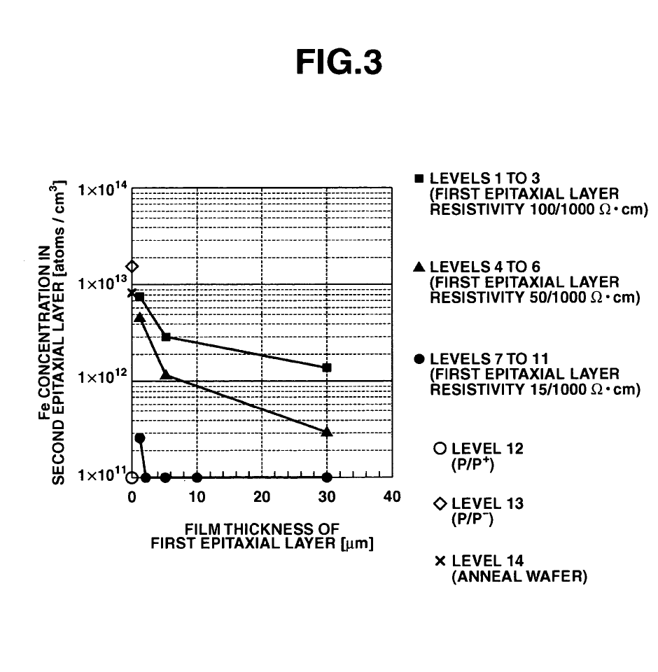

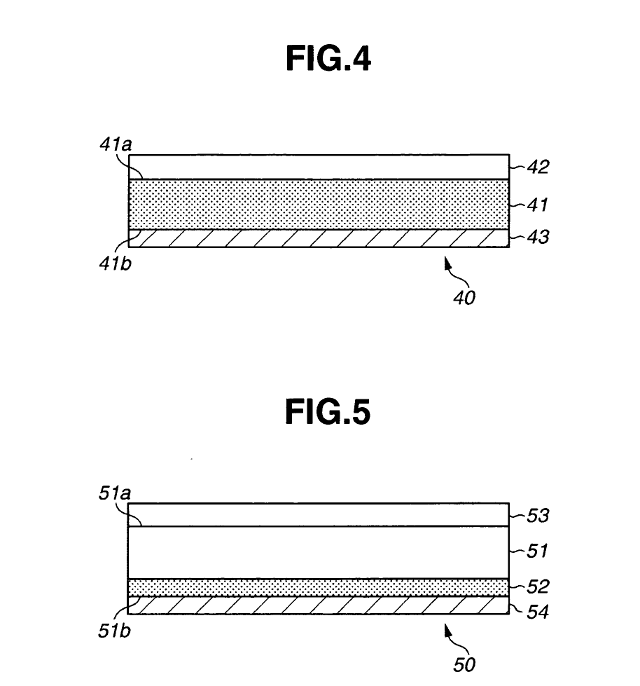

The same thermal process as the device fabrication process was then performed on each of the contaminant wafers (levels 1 to 14) and the concentration of residual Fe in the epitaxial layer on the surface was measured. The measurement results are shown in FIG. 3. DLTS was used as the measurement method. The gettering capacity of each wafer was investigated through reference to FIG. 3.

As shown in FIG. 3, the Fe concentration remaining in the surface of the epitaxial wafer (levels 1 to 11) according to the present invention is the same as or less than the Fe concentration remaining in the surface of a conventional epitaxial wafer or anneal wafer (levels 12 to 14). The fact that the Fe concentration remaining in the surface is low indicates that a large amount of Fe has been introduced to the gettering site. This signifies that there is a gettering capacity.

The important point here is that, although the results indicate that the larger the film thickness together with the epitaxial wafer of levels 1 to 3, levels 4 to 6, and levels 7 to 11, the lower the Fe concentration, there is a gettering capacity equal to or more than that of the conventional epitaxial wafer of levels 13, 14 even with a thin film thickness of about 1 (μm). That is, according to the present invention, sufficient gettering effects can be expected even in the case of a first epitaxial layer, that is, gettering site having a film thickness of about 1(μm). Further, the problems faced by conventional epitaxial wafers (auto-doping, metal contamination, and degree of flatness, and so forth) can also be resolved.

Misfit dislocation that occurs at the interface between the silicon substrate and epitaxial layer will be described next.

Because boron atoms are smaller than silicon atoms, misfit dislocation due to the difference in the crystal lattice constant occurs at the interface between two different silicon layers with a large boron concentration. This misfit dislocation has the beneficial effect that he misfit dislocation itself has a gettering capacity but, on the other hand, there are also the problems that strain in the periphery of the misfit dislocation is reflected at the wafer surface and minute unevenness is produced in the wafer surface. The advantages and disadvantages of such a misfit with respect to the device fabrication process vary according to the types, design rules, and design ideas, and so forth, of the devices.

When boron doping crystals with a resistivity of 4/1000 (Ω·cm) or less are employed for the silicon substrate in the P/P⁺ epitaxial wafers that were generally employed prior to the present invention, the misfit dislocation is reliably produced at the interface between the silicon substrate and epitaxial layer.

Table 3 shows the existence of misfit dislocation of two samples in which the resistivity (or concentration) of the first epitaxial layer is the same and the film thicknesses are different, according to the present invention.

TABLE 3

| | | Sample 1 | | Sample 2 | |
|---|---|---|---|---|---|
| First | Resistivity | 3/1000 | (Ω · cm) | 3/1000 | (Ω · cm) |
| epitaxial | Film | 1 | (μm) | 3 | (μm) |
| layer | thickness | | | | |
| Second | Resistivity | 10 | (Ω · cm) | 10 | (Ω · cm) |
| epitaxial | Film | 5 | (μm) | 5 | (μm) |
| layer | thickness | | | | |

| | | | |
|---|---|---|---|
| Misfit | After | No | Yes |
| occurrence | epitaxial | | |
| | growth | | |
| | After | No | Yes (further |
| | device | | increase imme- |
| | thermal | | diately after |
| | simulation | | epitaxial growth) |

As shown in Table 3, according to the present invention, even when misfit dislocation occurs in the first epitaxial layer of a certain resistivity, if the film thickness is changed while the resistivity is retained, the occurrence of misfit dislocation can be controlled.

Further, with the epitaxial wafer of the present invention, the following effects can also be expected.

A comparison of the characteristics of the epitaxial wafer of the present invention and conventional epitaxial wafers is shown in Table 4.

TABLE 4

| | P/P⁺ | P/P⁻ | Present invention |
|---|---|---|---|
| Latch-up resistance | ◯ | X | ◯ |
| High frequency conformity | X | ◯ | ◯ |

An epitaxial wafer with a conventional structure that is produced by stacking a single-layer epitaxial layer on a P⁺ silicon substrate (referred to as ‘P/P⁺’) possesses superior latch-up characteristics but cannot be said to possess a superior high-frequency conformity characteristic. Conversely, an epitaxial wafer with a conventional structure that is rendered by stacking a single-layer epitaxial layer on a P⁻ silicon substrate (referred to as ‘P/P⁻’) possesses a superior high-frequency conformity characteristic but cannot be said to possess a superior latch-up resistance characteristic.

On the other hand, the epitaxial wafer of the present invention possesses a latch-up resistance characteristic and superior high-frequency conformity characteristic that are to a certain extent superior.

The reason why the epitaxial wafer of the present invention possesses a superior high-frequency conformity characteristic is considered to be as follows:

When a high-frequency current flows to a high-frequency circuit in a device that is formed in the epitaxial layer of the P/P⁺ epitaxial wafer, an induced current flows to the P⁺ substrate of low resistivity. This induced current is transmitted by the P⁺ substrate and affects other circuits, thus constituting high-frequency noise. Because the whole of the substrate of the P/P⁺ epitaxial wafer is P⁺, the induced current grows. On the other hand, the P⁺ layer of the present invention is thin and, therefore, the production of the induced current is small and does not readily flow. Accordingly, the present invention makes it possible to reduce high-frequency noise.

Furthermore, the present invention has a P/P⁺/P⁻ structure, and, therefore, a P⁺ first epitaxial layer fulfils the role of a P⁺ substrate in a conventional P/P⁺ structure. That is, the present invention also possesses latch-up resistance.

### INDUSTRIAL APPLICABILITY

The present invention can be applied to the fabrication fields of semiconductor epitaxial wafers that are used for CPUs or memories such as DRAM.

1-4. (canceled)

5. A semiconductor epitaxial wafer having an epitaxial layer stacked on a semiconductor substrate, wherein:
plural epitaxial layers are stacked on a front side of the semiconductor substrate; and
an impurity concentration of any one of the plural epitaxial layers is high enough to afford a latch-up resistance and a high-frequency conformity and is higher than impurity concentrations of the semiconductor substrate and other epitaxial layers.

6. A semiconductor epitaxial wafer having an epitaxial layer stacked on a semiconductor substrate, wherein:
plural epitaxial layers are stacked on a front side of the semiconductor substrate;
an impurity concentration of any one of the plural epitaxial layers is high enough for the formation of a gettering site and is higher than impurity concentrations of the semiconductor substrate and other epitaxial layers; and
an impurity concentration of the semiconductor substrate is at a level of suppressing impurity discharge from the semiconductor substrate.

7. The semiconductor epitaxial wafer according to claim 5, wherein an impurity concentration of the epitaxial layer being in contact with the semiconductor substrate among the plural epitaxial layers is higher than the impurity concentrations of the semiconductor substrate and the other epitaxial layers.

8. A semiconductor epitaxial wafer having an epitaxial layer stacked on a semiconductor substrate, wherein:
plural epitaxial layers are stacked on a front side of the semiconductor substrate;
an impurity concentration of a high-concentration epitaxial layer among the plural epitaxial layers is 2.77×10¹⁷ to 5.49×10¹⁹ (atoms/cm³); and
an impurity concentration of the semiconductor substrate is 1.22×10¹⁴ to 1.46×10¹⁶ (atoms/cm³).

9. A semiconductor epitaxial wafer having an epitaxial layer stacked on a semiconductor substrate, wherein:
plural epitaxial layers are stacked on a front side of the semiconductor substrate;
a resistivity of a high-concentration epitaxial layer among the plural epitaxial layers is 0.002 to 0.1 (Ωcm); and
a resistivity of the semiconductor substrate is 1 to 100 (Ωcm).

10. The semiconductor epitaxial wafer according to claim 5, wherein a high-concentration epitaxial layer among the plural epitaxial layers contains boron.
